(19) United States
(12) Patent Application Publication
(10) Pub. No.: US 2008/0176422 A1
(43) Pub. Date: Jul. 24, 2008

(54) Emc Connector Assembly

(76) Inventor: Niklas Philipsson, Kista (SE)

Correspondence Address: NIXON & VANDERHYE, PC, 901 NORTH GLEBE ROAD, 11TH FLOOR, ARLINGTON, VA, 22203, US

(21) Appl. No.: 11/794,546

(22) PCT Filed: Jan. 3, 2005
(86) PCT No.: PCT/SE05/00003

§ 371 Date: Dec. 19, 2007

(51) Int. Cl. H01R 12/00

(52) U.S. Cl. 439/76.1

(57) ABSTRACT

The invention relates to a connector assembly for an electronic device. The electronic device is provided on a PCB and located inside a cavity exhibiting a high degree of electromagnetic shielding. A connector is surface mounted on the PCB and essentially the entire connector is located inside the same cavity as the electronic device.

### FIELD OF THE INVENTION

The present invention relates to a connector assembly for transmitting electrical signals in a broad aspect into and out of a cavity of an electronic device.

### BACKGROUND OF THE INVENTION

In many radio applications involving integrated transmitters/receivers (TRX) and power units on the same PCB, shielding is of great importance. In particular it is important to shield the receiving unit, in view of the high energies involved in the transmission of radio signals, and because the transmitter is arranged very close to the receiver on the PCB.

Each separate unit on a PCB is enclosed in what is commonly termed a “cavity”. An enclosure is conventionally formed by a cover having a lid portion and walls defining the cavity, the cover being provided in a sealing fashion on top of the PCB. In order to feed undisturbed signals from the exterior (e.g. via a cable) into such a cavity, the signal must be shielded all the way from the cable via the enclosure and into the cavity. A crucial element in the chain of devices for feeding a signal into said cavity is the connector by means of which the external cable is connected to the TRX unit.

In the prior art, connectors are hole mounted on the PCB, by a “pin in paste” method, but outside the cavity to which the signal is to be fed. Hole mounting of this kind comprises inserting a pin that extends downwards from the connector (i.e. at an angle of 90° with respect to the direction in which the signal is fed into the connector), the pin carrying the signal, into a hole in the PCB via a solder such that the connector is rigidly attached onto the PCB. Thus the pin extends down through the PCB and connects to a lead, i.e. there will be a second 90° bend. The signal is than carried on the underside of the PCB in said lead, which is provided in a recess in the enclosure (rather the cooler/frame) thereby providing proper shielding, to a point underneath the cavity into which the signal is to be fed. At this point of entry, the lead is again bent 90° upwards, and passed through the PCB into the cavity, where it finally is bent 90° again and then attached to the relevant component.

There are several drawbacks with this connector technology.

First of all the connector is hole mounted, i.e. it is not surface mounted which is in general desirable for all components to be attached on a PCB. Hole mounting, where connecting pins provided on a component to be attached to a PCB, are inserted in holes in the PCB and soldered, often requires manual operations, e.g. soldering by hand, or by special processes which adds to manufacture time and cost.

Secondly, the signal strength is reduced by the four bends that are required in order to pass the lead into the cavity.

Thirdly, in view of the fact that the connector is provided outside the cavity, there will be less available PCB surface, which can be crucial for modern applications, where the component density is ever increasing in order to save space. As much as 6 cm² extra PCB area can be made available for a standard DTRU (Double Transmitting Receiving Unit) device.

In addition, the mechanical strength leaves more to be desired. In particular the connector is subjected to relatively strong bending forces when a cable is to be connected, because frequently appropriate tools are not used, whereby the connector may simply be pulled off the PCB.

Finally, the shielding is relatively complex, in that there is required both external (outside the cavity and enclosure), and internal shielding (outside the cavity but inside the enclosure).

The total cost of a connector of the type described is fairly high.

In another prior art method a connector is attached by screwing it onto the underside of the PCB, and manually soldering leads to components. Obviously this is also a labour intensive and thus costly method.

### SUMMARY OF THE INVENTION

Thus, in view of the drawbacks and problems associated with the prior art connectors, there is a need for an improved connector, that can be surface mounted, exhibits improved electrical and mechanical performance, and that can be produced and mounted at a lower cost then the prior art devices.

This is achieved in accordance with invention by a connector assembly as defined in claim 1.

An important feature of the invention is that basically the entire connector is located inside the cavity (of course the actual contact member is exposed in order to be accessible for connection of a cable) and is secured in place by the cover pressing the connector against the PCB, to which it is soldered by surface mounting means and methods. Another important feature is that the signal path is straight all the way from the exterior and into the cavity to the point of attachment to the relevant component, i.e. there are no bends that otherwise would reduce the signal strength.

Furthermore, the cost of manufacture of the connector is reduced.

Other features of the present invention are defined in the depending claims.

### BRIEF DESCRIPTION OF THE DRAWINGS

Further scope of applicability of the present invention will become apparent from the detailed description given hereinafter and the accompanying drawings which are given by way of illustration only, and thus not to be considered limiting on the present invention, and wherein

FIG. 1 is a view from above of a prior art printed circuit board for a TRX unit with connectors;

FIG. 2 a view from above of a printed circuit board for a TRX unit with connector assemblies according to the present invention;

FIG. 3a is a schematic perspective view of a connector usable with the invention;

FIG. 3b is a view from above of a connector as shown in FIG. 3a mounted on a PCB, and with the top part of the connector broken away;

FIG. 3c schematically shows an alternative geometry of a connector; and

FIG. 4 is a front view of a connector assembly according to the present invention.

### DETAILED DESCRIPTION OF PREFERRED EMBODIMENTS

The present invention will have broad utility for connectors in general, both in signal transmission (analogue as well as digital) and for power transmission, the general inventive concept being defined in the appended claims. However, the invention will primarily be illustrated herein with an embodiment comprising a coaxial cable connector for the transmission of analogue radio signals.

In general terms, according to the invention, there is provided a connector assembly for an electronic device. The electronic device is provided on a PCB and inside a cavity exhibiting a high degree of electromagnetic shielding. The connector is mounted on the PCB and essentially the entire connector is located inside the same cavity as the electronic device. Furthermore, the contact surface between the connector and the cavity wall is electromagnetically leak proof. The connector is preferably surface mounted on the PCB.

More in particular, the connector assembly further comprises a metal frame on which the PCB is mounted, and a metal cover member forming the cavity and providing the shielding of the cavity. A cavity lane, provided on the PCB, defines together with the cover member the cavity. The connector has a front part adapted to receive a mating connector attached on a cable, and a rear part connected to the front part by a centre pin. The cover member presses on the connector along its outer surface to enclose the rear part of the connector in said cavity, only exposing the front part of the connector. The cover member has a wall indentation mating with the outer surface profile of the connector, so as to provide a sealing function when the cover is attached, and preferably there is provided an electrically conductive sealing material between the cover member and the surface of the connector outer surface.

In a particularly preferred embodiment, the assembly according to the invention the connector forms part of the cavity lane surrounding the cavity to which the connector is coupled. The connector is preferably a coaxial connector, although other types of connectors are possible.

The invention is suitably implemented i.a. in a base station of a telecommunications system.

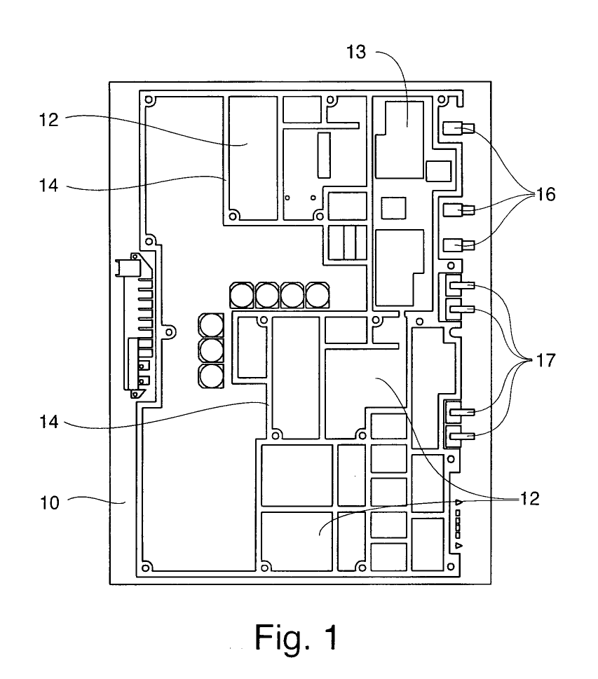

FIG. 1 illustrates in a view from above a printed circuit board (PCB) 10 for a DTRU unit, provided with connectors according to the prior art. The PCB 10 on which the DTRU is built is subdivided in a plurality of so called cavities (a few of which are indicated with reference numeral 12), each of which will be enclosed by metal walls and a roof provided by a cover member (not shown) of metal, suitably aluminium, placed on top of the PCB. Inside the cavities there are some kind of electronic devices 13 mounted. The pattern of metal tracks provided on the PCB, and encircling each cavity forms what is referred to as cavity lanes 14. The cover is clamped onto the PCB with a certain pressure to provide a tight seal. Furthermore, the cover is provided with a conductive sealing material (gasket) on the wall portions resting against the cavity lanes 14, thereby providing a complete enclosure, and an efficient electromagnetic shield. The conductive sealing means 51 extends along the walls of the parts of the cover member that define the cavity/cavities.

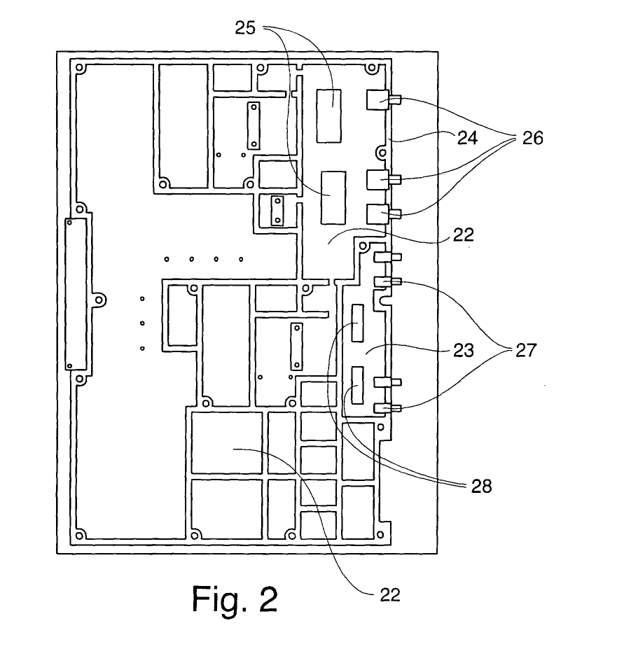

The entire PCB rests on a frame member (not shown in FIG. 1 or 2) made of metal. The bottom surface of the PCB is gold plated to provide good thermal contact with the cooler.

As can be clearly seen in FIG. 1, there are a number of connectors 16, 17 mounted on the PCB 10. However, these connectors are mounted outside the pattern defining the cavity structure. As discussed in the Background section, these connectors are hole mounted, which is accompanied by a number of drawbacks.

FIG. 2 illustrates a PCB for a DTRU unit embodying the invention. As can be seen, the difference from FIG. 1 is that the connectors 26, 27 are located essentially entirely within respective cavities 22, 23. Furthermore, a connector actually forms part of a cavity lane 24. This is made possible by a novel design of the connector 26, 27 and of the cover member, respectively, details of which will now be described below. Electronic devices located inside the cavities are designated 25 and 28.

To each cavity there can of course be associated a plurality of connectors, such that a plurality of cables can be connected to the device(s) located inside a cavity.

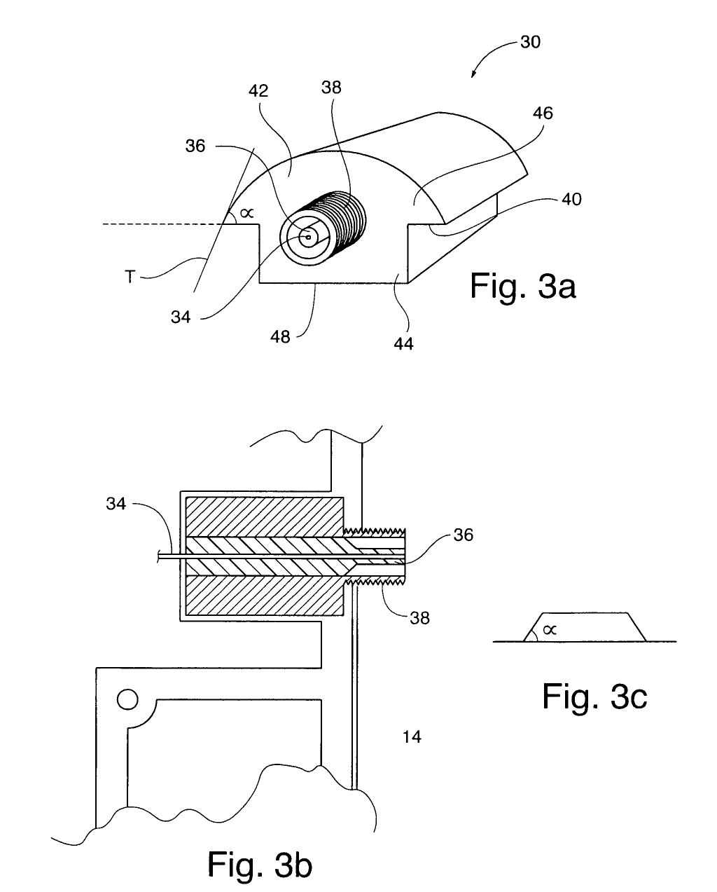

Thus, in FIG. 3a-b there is disclosed a coaxial connector 30 for use in one embodiment of the present invention.

The connector 30 comprises a metal body. This metal body houses a coaxial conductor configuration, comprising a signal transmitting member 34 referred to as a centre pin (shown in phantom lines in FIG. 3b), which extends through the connector body from the input end, i.e. the front of the connector (facing out towards the exterior) where the mating contact of a signal cable can be attached, and to the output end at the rear. The centre pin 34 is embedded in an insulating cylinder 36, made of a dielectric material, which in turn is enclosed in a cylindrical protrusion 38 forming the secondary conductor of the coaxial configuration. This assembly of a centre pin 34 (signal transmitting member) 34, and an insulation 36, is embedded in the metal body. These elements together form a shielded coaxial connector meeting the EMC requirements for radio applications.

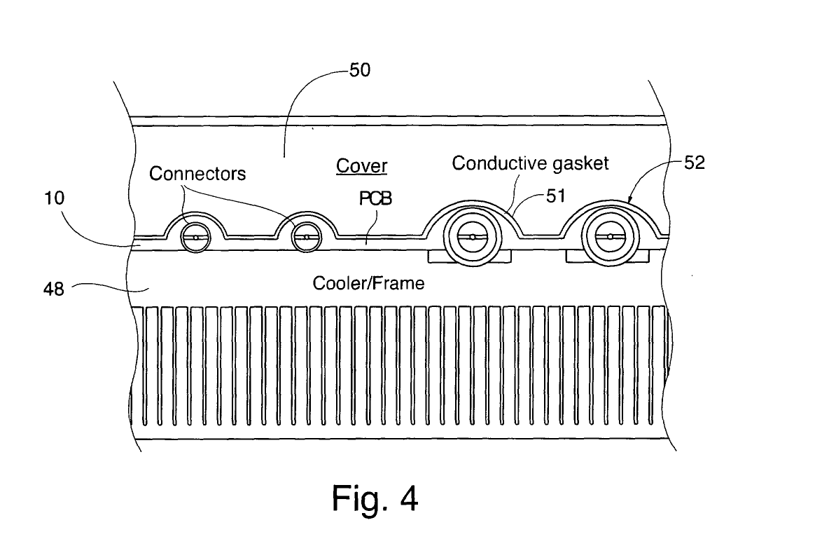

The connector 30 is designed such that it can be surface mounted on the PCB. In a preferred embodiment the metal body has a lower, essentially box-shaped portion 44 integral with an upper portion 42, whereby the width of the box-shaped portion 44 is smaller than the width of the upper portion 42, such that there are formed flange-like members 46, the undersides of which constitute the required contact surfaces 40 for bonding to the PCB. This embodiment requires that there is provided a cut-in portion in the PCB where the connector is to be mounted, for accommodating the lower box portion 44. In a mounted position, the (lower) contact surfaces 40 of the flange portions 46 will rest against cavity lanes, provided along the edges of said cut-in portion of the PCB, and the bottom surface 48 of the lower portion 44 of the connector 30 will rest against a conductive foam in order to achieve contact between the component and the cooler/frame member for grounding. This can be clearly seen in FIG. 4. One important reason for designing the connector as described above is that it is desirable that the centre pin 34 can be provided within the connector without bending, since as already mentioned, bends yield signal strength reduction. Namely, if the connector were to be mounted on the PCB with its entire bottom surface soldered or bonded thereto, the centre pin would inevitably be provided at a slightly more elevated position, necessitating bending, due to the need to provide a relatively thick insulation between the centre pin and the tube member 38. Also, the mechanical strength would probably be impaired. However, it would still be within the inventive concept to mount the connector in this way, i.e. with the entire bottom surface bonded to the PCB.

Thus, in a preferred embodiment the metal body 32 is provided with flat flange portions 40, extending along the edges of the connector, and facing downwards so as to contact a cavity lane 14 on the PCB when the connector is placed in the appropriate position in the cut-out portion of the PCB. Suitably the flange portions 40 are bonded to the cavity lane 14 along the edge of the connector, whereby the connector body 32 itself will form a part of the cavity lane.

In the embodiment of a connector shown in FIG. 3a-b, the metal body 32 has an upper portion 42 which is curved. This curved surface connects to the cavity lane 14 at an angle α that preferably will not be greater than 60°, and is preferably smaller than 45°. The reason for this is that if the angle α is too large, it cannot be guaranteed that the cover member will adequately seal against the connector top surface when attached onto the PCB. This will be further explained below.

The angle α is for this embodiment defined as that angle which a tangent T forms with respect to the plane of the PCB (indicated with a broken line in FIG. 3a), on the surface of the connector at a point elevated from the PCB, corresponding to the thickness of the sealing material (described below).

It is possible to provide a connector geometry that differs from the curved geometry described above, namely by providing a trapezoid cross-section, as shown in FIG. 3c. Thereby the angle α will correspond to the inclination of the sloping sides of the body.

FIG. 4 illustrates a connector assembly according to the present invention in a front view.

The entire assembly comprises a cooler/frame member 48, on which a PCB 10 rests. A plurality of connectors 30 are surface mounted to the PCB as described above, i.e. inserted in cut-out portions in the PCB and bonded or soldered to cavity lanes on the PCB 10. On top of the PCB there is provided a cover 50 made of metal.

The cover comprises a top lid covering the entire PCB, and is subdivided in partitions forming a pattern of walls corresponding to the pattern of cavity lanes on the PCB, such that cavities (as defined above) are formed when the cover is pressed against the PCB. The cavities thus formed will be electromagnetic compatible (EMC) and the PCB will have a proper EMC design.

In order to provide a tight seal between the cavity lanes on the PCB and the cover member, there is provided a conductive gasket 51 on the cover. The gasket is made of a conductive polymer material, such as conductive silicone. This material is applied to the cover member in a viscous state by a dispensing procedure. The amount of gasket material should be such that the EMR value is less than −85 dBc when the leakage of radiation is measured at the gasket. The cover is attached to the PCB by clamping such that the gasket material is slightly compressed. The thickness of the gasket material when the cover is appropriately mounted on top of the PCB should be about 1 mm for the application shown. However, this is of course subject to variations depending on several factors, such as i.a. the composition of the gasket material.

In accordance with the present invention, the front wall of the cover member is provided with recesses, in FIG. 4 shown as almost semi-circular notches or indentations 52, exactly conforming to the exterior shape of the top, curved portion 42 of the connector 30. The cover will press against the connector with the gasket material 51 in between, and this clamping of the connector to the PCB will increase the mechanical strength substantially.

One important feature for optimum performance of the connector assembly is the angle α mentioned above, i.e. the angle at which the curved top surface of the connector connects to the cavity lane to which it is bonded/soldered. As mentioned above, the notch of the cover member that accommodates the connector conforms to the curved shape of the connector, and thus exhibits the same angle α at the transition between the notch 52 and the straight bottom edge of the cover member. If the angle is too sharp, it will be difficult to apply the gasket material sufficiently accurately at this transition point to ensure that a proper filling of the space at the angle in question will be achieved, when the cover is mounted over the PCB. As mentioned, the angle α should not be not greater than 60°, preferably not greater than 45°

Although the invention has been described with reference to a coaxial connector, it is to be understood that the basic inventive concept is usable for many other kinds of electrical lead-through applications, such as power connectors, LF connectors, cable lead-throughs, and optical interfaces.

The primary advantages with the invention is that the cost of manufacture of the connector is reduced, more PCB area is made available, electrical performance of the connectors is improved, and the mechanical strength is improved. Also the mounting cost will be lower.

1. A connector assembly for an electronic device, said electronic device provided on a PCB, the assembly comprising a cavity defined by the PCB, a cavity lane and a cover members
wherein
essentially the entire connector is located inside the cavity; and
conductive sealing means are provided along the contact surface between the connector and the walls of the cavity.

2. The connector assembly as claimed in claim 1, wherein
a metal cover member forming the cavity and its walls;
said connector having a front part adapted to receive a mating connector attached on a cable, and a rear part connected to the front part by a centre pin; wherein
the cover members presses on the connector along its outer surface to enclose the rear part of the connector in said cavity, only exposing the front part of the connector.

3. The assembly as claimed in claim 1, wherein the connector is surface mounted on the PCB.

4. The assembly as claimed in claim 1, wherein the cover member has a wall indention mating with the outer surface profile of the connector, so as to provide a sealing function when the cover is attached.

5. The assembly as claimed in claim 1, wherein the conductive sealing means extends along the walls of the parts of the cover member that define the cavity.

6. The assembly as claimed in claim 4, wherein the angle α at which the top surface of the connector connects to the cavity lane to which it is attached is less than 60°, preferably less than 45°.

7. The assembly as claimed in claim 6, wherein the angle α is defined as that angle which a tangent forms with respect to the plane of the PCB, on the surface of the connector at a point elevated from the PCB, corresponding to the thickness of the sealing material, or if the connector is not curved, the angle α corresponds to the inclination of the sloping sides of the connector body.

8. The assembly as claimed in claim 2, wherein the connector forms part of the cavity lane surrounding the cavity to which the connector is coupled.

9. The assembly as claimed in claim 1, wherein the connector is a coaxial connector.

10. A base station comprising at least one connector assembly as claimed claim 1.

11. A telecommunications system comprising a base station as claimed in claim 10.
